(19) United States
(12) Patent Application Publication
(10) Pub. No.: US 2021/0294138 A1
(43) Pub. Date: Sep. 23, 2021

(54) ACTIVE MATRIX SUBSTRATE AND METHOD FOR MANUFACTURING SAME

(71) Applicant: Sharp Kabushiki Kaisha, Sakai City, Osaka (JP)

(72) Inventors: Hideki KITAGAWA, Sakai City (JP); Tohru DAITOH, Sakai City (JP); Hajime IMAI, Sakai City (JP); Tetsuo KIKUCHI, Sakai City (JP); Masahiko SUZUKI, Sakai City (JP); Toshikatsu ITOH, Sakai City (JP); Teruyuki UEDA, Sakai City (JP); Setsuji NISHIMIYA, Sakai City (JP); Kengo HARA, Sakai City (JP)

(21) Appl. No.: 16/336,483

(22) PCT Filed: Sep. 19, 2017
(86) PCT No.: PCT/JP2017/033633

§ 371 Date: Mar. 26, 2019

(30) Foreign Application Priority Data
Sep. 27, 2016 (JP) 2016-187779

(51) Int. Cl. G02F 1/1368; H01L 27/12

(52) U.S. Cl. CPC G02F 1/1368; H01L 27/127; H01L 27/1225; H01L 27/1248

(57) ABSTRACT

A pixel area in the active matrix substrate 100 includes a thin film transistor 101 that has an oxide semiconductor layer 7, an inorganic insulating layer 11 and an organic insulating layer 12 that cover a thin film transistor, a common electrode 15, a dielectric layer 17 that primarily contains silicon nitride, and a pixel electrode 19. The inorganic insulating layer has a multi-layered structure that includes a silicon oxide layer and a silicon nitride layer. A pixel electrode 10 is brought into contact with a drain electrode 9 within a pixel contact hole. The pixel contact hole is configured with a first opening portion, a second opening portion, and a third opening portion that are formed in the inorganic insulating layer 11, the organic insulating layer 12, and the dielectric layer 17, respectively. A flank surface of the first opening portion and a flank surface of the second opening portion are aligned. The flank surface of the second opening portion includes a first portion 121 that is inclined at a first angle θ1 with respect to a substrate, a second portion 122 that is positioned above the first portion and is inclined at a second angle θ2 that is greater than the first angle, and a border 120 that is positioned between the first portion and the second portion and of which an inclination angle with respect to the substrate discontinuously changes.

### TECHNICAL FIELD

The present invention relates to an active matrix substrate that is formed using an oxide semiconductor, and a method for manufacturing the active matrix substrate.

### BACKGROUND ART

An active matrix substrate that is used in a liquid crystal display device or the like includes a switching element, such as a Thin Film Transistor (hereinafter referred to as “TFT”), for every pixel. As this switching element, a TFT of which an active layer is an amorphous silicon film (hereinafter referred to as “amorphous silicon TFT”), or a TFT of which an active layer is a polycrystalline silicon film (hereinafter referred to as “polycrystalline silicon TFT”) has been widely used in the related art.

The active matrix substrate is employed in a liquid crystal display device that operates in various operation modes. For example, PTL 1 discloses an active matrix substrate that possibly finds application in liquid crystal display devices which operate in an operation mode in compliance with a transverse electric field method, such as a Fringe Field Switching (FFS mode). In this active matrix substrate, in each pixel, a common electrode and a pixel electrode are provided over a TFT with an insulating film in between. An opening in the shape of a slit is formed in an electrode (for example, the pixel electrode) that is positioned toward a liquid crystal layer, among these electrodes. Accordingly, an electric field is generated that is expressed as a line of electric force which gets out of the pixel electrode, passes through the liquid crystal layer and further through the opening in the shape of a slit, and gets to the common electrode. This electric field has a component in the horizontal direction with respect to the liquid crystal layer. As a result, the electric field in the horizontal direction can be applied to the liquid crystal layer.

In recent years, in some cases, instead of amorphous silicon or polycrystalline silicon, an oxide semiconductor has been used as a material of an active layer of the TFT that is used in the active matrix substrate. This TFT is referred to as “oxide semiconductor TFT”. The oxide semiconductor has higher mobility than the amorphous silicon. For this reason, it is possible that the oxide semiconductor TFT operates at a higher speed than the amorphous silicon TFT. It is known that a TFT (hereinafter referred to as “oxide semiconductor TFT”) of which an active layer is an oxide semiconductor layer is used. The oxide semiconductor has higher mobility than the amorphous silicon. For this reason, it is possible that the oxide semiconductor TFT operates at a higher speed than the amorphous silicon TFT.

On the other hand, technologies are known that monolithically (integrally) provide a drive circuit, such as a gate driver or a source driver, on a substrate. In recent years, technologies that manufacture these drive circuits (monolithic drivers) using the oxide semiconductor TFT has been used. In the present specification, for distinction between two types of TFTs, a TFT that constitutes the drive circuit is referred to “circuit TFT” and a TFT that is provided as a switching element in each pixel is referred to as “pixel TFT”.

Normally, an oxide semiconductor TFT that is formed on the active matrix substrate is covered with an insulating protection film (a passivation film) such as an inorganic insulating film. In some cases, an organic insulating layer for flattening is further formed on the passivation.

Incidentally, in the oxide semiconductor TFT, for example, when the oxide semiconductor layer is process-damaged, oxygen deficiency occurs in the oxide semiconductor layer and thus resistance of the oxide semiconductor is lowered. Therefore, there is a likelihood that a desired TFT characteristic will not be obtained. Thus, it is known that, for the purpose of reducing the oxygen deficiency in the oxide semiconductor layer, an insulating layer (for example, an oxide silicon layer) that contains oxygen is used as the passivation film. For example, PTL 2 discloses that the passivation film which has a multi-layered structure that includes a silicon oxide layer and a silicon nitride layer is used. This passivation film is referred to as “multi-layered passivation film”. In the oxide semiconductor TFT that has a bottom gate structure, the silicon oxide layer is used as the lowermost layer (that is, a layer that is brought into contact with the oxide semiconductor layer) of a multi-layered passivation film. Thus, there is a likelihood that oxygen that is contained in the silicon oxide layer makes up for the oxygen deficiency that occurs in the oxide semiconductor layer. Furthermore, the silicon nitride layer is superior to the silicon oxide layer in preventing water or impurities from being diffused. Therefore, when the multi-layered passivation film is used, penetration of water or the like into the oxide semiconductor layer can be suppressed more effectively than in a case where the silicon oxide film is used as a single layer.

### CITATION LIST

### Patent Literature

PTL 1: Japanese Unexamined Patent Application Publication No. 2010-243894
PTL 2: International Publication No. 2012/029644

### SUMMARY OF INVENTION

### Technical Problem

However, as a result of the research by the present inventor, it was understood that, in some cases, it was difficult to form a pixel contact hole that has a desired shape, when the multi-layered passivation film described above was used in the active matrix substrate that finds application in the liquid crystal display device that operates in the operation mode in compliance with the transverse electric field method. The “pixel contact hole” is an opening portion that is provided in an inter-layer insulating layer in order to connect the pixel electrode and the pixel TFT. When the processability of the pixel contact hole decreases, there is a concern that the coatability of the pixel electrode that is formed within the pixel contact hole will decrease, thereby resulting in disconnection caused by step. This can be a factor in decreasing the reliability of the active matrix substrate. A result of the detailed research by the present inventor will be described below.

An object of an embodiment of the present invention, which was made in view of the situation described above, is to provide a high-reliability active matrix substrate includes an oxide semiconductor TFT.

### Solution to Problem

According to an embodiment of the present invention, there is provided an active matrix substrate that includes multiple pixel areas, each including: a substrate; a thin film transistor that is supported on the substrate and has an oxide semiconductor layer as an active layer; an inorganic insulating layer that is formed in such a manner as to cover the thin film transistor; an organic insulating layer that is formed on the inorganic insulating layer; a common electrode that is positioned on the organic insulating layer; a pixel electrode that is positioned on the common electrode with a dielectric layer in between; and a pixel contact portion that electrically connects the pixel electrode and a drain electrode of the thin film transistor, in which the inorganic insulating layer has a multi-layered structure that includes a silicon oxide layer which primarily contains silicon oxide, and a silicon nitride layer which is positioned on the silicon oxide layer and primarily contains silicon nitride, in which the dielectric layer primarily contains the silicon nitride, in which the pixel electrode is brought into contact with the drain electrode within a pixel contact hole that is provided in the inorganic insulating layer, the organic insulating layer, and the dielectric layer, in which the pixel contact hole is configured with a first opening portion, a second opening portion, and a third opening portion which are formed in the inorganic insulating layer, the organic insulating layer, and the dielectric layer, respectively, in which a flank surface of the first opening portion and a flank surface of the second opening portion are aligned, and in which the flank surface of the second opening portion includes a first portion that is inclined at a first angle with respect to the substrate, a second portion that is positioned above the first portion and is included at a second angle that is greater than the first angle, with respect to the substrate, and a border that is positioned between the first portion and the second portion and of which an inclination angle with respect to the substrate discontinuously changes.

In a certain embodiment, the third opening portion is positioned within the first opening portion and the second opening portion, when viewed from a direction normal to the substrate 1.

In a certain embodiment, at the border, an angle that the first portion and the second portion make with respect to each other is equal to or greater than 120° and is equal to or smaller than 170°.

According to another embodiment of the present invention, there is provided an active matrix substrate that includes multiple pixel areas, each including: a thin film transistor that is supported on the substrate and has an oxide semiconductor layer as an active layer; an inorganic insulating layer that is formed in such a manner as to cover the thin film transistor; an organic insulating layer that is formed on the inorganic insulating layer; a common electrode that is positioned on the organic insulating layer; a pixel electrode that is positioned on the common electrode with a dielectric layer in between; and a pixel contact portion that electrically connects the pixel electrode and a drain electrode of the thin film transistor, in which the inorganic insulating layer has a multi-layered structure that includes a silicon oxide layer which primarily contains silicon oxide, and a silicon nitride layer which is positioned on the silicon oxide layer and primarily contains silicon nitride, in which the dielectric layer primarily contains the silicon nitride, in which the pixel electrode is brought into contact with the drain electrode within a pixel contact hole that is provided in the inorganic insulating layer, the organic insulating layer, and the dielectric layer, in which the pixel contact hole is configured with a first opening portion, a second opening portion, and a third opening portion which are formed in the inorganic insulating layer, the organic insulating layer, and the dielectric layer, respectively, in which at least a portion of the flank surface of the first opening portion is covered with the organic insulating layer, and in which the third opening portion is positioned within the first opening portion and the second opening portion, when viewed from the direction normal to the substrate.

In a certain embodiment, the second opening portion is positioned within the first opening portion, when viewed from the direction normal to the substrate.

In a certain embodiment, only a part of the second opening portion is positioned within the first opening portion, when viewed from the direction normal to the substrate.

In a certain embodiment, the active matrix substrate that include multiple pixel areas, each further including a terminal portion, in which the terminal portion includes a source connection portion that is positioned on the gate insulating layer, the inorganic insulating layer that extends on the source connection portion, the dielectric layer that extends on the inorganic insulating layer and is brought into contact with an upper surface of the inorganic insulating layer, and an upper connection portion that is positioned on the dielectric layer, in which the upper connection portion is brought into contact with the source connection portion within a terminal-portion contact hole that is formed in the inorganic insulating layer and the dielectric layer, the terminal-portion contact hole is configured with a fourth opening portion and a fifth opening portion that are formed in the inorganic insulating layer and the dielectric layer, respectively, and, when viewed from the direction normal to the substrate 1, the fifth opening portion is positioned within the fourth opening portion, and a flank surface of the fourth opening portion is covered with the dielectric layer.

In a certain embodiment, the thin film transistor has a channel etch structure.

In a certain embodiment, the oxide semiconductor layer of the thin film transistor contains an In—Ga—Zn—O-based semiconductor.

In a certain embodiment, the oxide semiconductor layer contains a crystalline portion.

In a certain embodiment, the oxide semiconductor layer has a multi-layered structure.

According to still another embodiment of the present invention, there is provided a method of manufacturing an active matrix substrate, the method including: (a) a process of forming a thin film transistor of which an active layer is an oxide semiconductor layer, on a substrate; (b) a process of forming an inorganic insulating layer in such a manner as to cover the thin film transistor, the process in which the inorganic insulating layer has a multi-layered structure that includes a silicon oxide layer which primarily contains silicon oxide, and a silicon nitride layer which is positioned on the silicon oxide layer and primarily contains silicon nitride; (c) a process of forming on the inorganic insulating layer an organic insulating layer that has a second opening portion through which a portion of the inorganic insulating layer is exposed; (d) a process of forming a resist mask on an upper surface of the organic insulating layer and a portion of a flank surface of the second opening portion, the process in which an end portion of the resist mask is positioned on the flank surface of the second opening portion and in which a portion of the organic insulating layer is exposed through the resist mask; (e) a process of performing patterning of the inorganic insulating layer using the resist mask, the process in which, by performing the patterning, not only is formed a first opening portion through which a portion of the drain electrode is exposed, in the inorganic insulating layer, but a surface layer of a portion that is exposed through the resist mask, of the organic insulating layer is also etched; (f) a process of forming a common electrode on the organic insulating layer; (g) a process of forming on the organic insulating layer a dielectric layer that is positioned within the second opening portion and first opening portion and has a third opening portion through which a portion of the drain electrode is exposed, the process in which the dielectric layer primarily contains silicon nitride; and (h) a process of forming a pixel electrode that is brought into contact with the drain electrode within the pixel contact hole, on the dielectric layer and within the pixel contact hole.

According to still another embodiment of the present invention, there is provided a method of manufacturing the active matrix substrate, the method including: (a) a process of forming a thin film transistor of which an active layer is an oxide semiconductor layer, on a substrate; (b) a process of forming an inorganic insulating layer in such a manner as to cover the thin film transistor, the process in which the inorganic insulating layer has a multi-layered structure that includes a silicon oxide layer which primarily contains silicon oxide, and a silicon nitride layer which is positioned on the silicon oxide layer and primarily contains silicon nitride; (c) a process of forming a first opening portion through which a portion of a drain electrode of the thin film transistor is exposed, in the inorganic insulating layer; (d) a process of forming on the inorganic insulating layer and within the first opening portion an organic insulating layer that is positioned in such a manner as to cover at least a portion of a flank surface of the first opening portion and has a second opening portion through which a portion of the drain electrode is exposed; (e) a process of forming a common electrode on the organic insulating layer; (f) a process of forming on the organic insulating layer a dielectric layer that has an third opening portion that is positioned within the second opening portion and the first opening portion and through which a portion of the drain electrode is exposed, the process in which the dielectric layer primarily contains silicon nitride and in which, when viewed from a direction normal to the substrate, the third opening portion is positioned within the first opening portion and the second opening portion; and (g) a process of forming a pixel electrode that is brought into contact with the drain electrode within a pixel contact hole, on the dielectric layer and within the pixel contact hole that is configured with the first opening portion, the second opening portion, and the third opening portion.

### Advantageous Effects of Invention

According to the embodiment of the present invention, an active matrix substrate that includes an oxide semiconductor and includes a high-reliability oxide semiconductor TFT and a method of manufacturing the active matrix substrate.

### BRIEF DESCRIPTION OF DRAWINGS

FIG. 1(a) is a schematic plan-view diagram illustrating a portion of one pixel area in an active matrix substrate 100 according to the present embodiment. FIGS. 1(b) and 1(c) are schematic cross-sectional diagrams, each illustrating an example of a pixel contact portion 102 and an oxide semiconductor TFT 101 in the active matrix substrate 100.

FIGS. 2(a) to 2(e) are process-related cross-sectional diagrams, each illustrating an example of a method of manufacturing a pixel contact portion and a terminal portion in the active matrix substrate 100.

FIGS. 3(a) and 3(b) are process-related cross-sectional diagrams, each illustrating an example of the method of manufacturing the pixel contact portion and the terminal portion in the active matrix substrate 100.

FIG. 4 is a diagram illustrating a cross-sectional SEM image of the pixel contact hole in the active matrix substrate 100.

FIG. 5(a) is a schematic plan-view diagram illustrating a portion of one pixel area in an active matrix substrate 200 according to a second embodiment. FIG. 5(b) is a schematic cross-sectional diagram illustrating an example of a pixel contact portion 202 in the active matrix substrate 200. FIGS. 5(c) and (d) are schematic plan-view diagrams, each illustrating a modification example of a pixel contact hole CH1 in the pixel contact portion 202.

FIGS. 6(a) to 6(f) are process-related cross-sectional diagrams, each illustrating an example of a method of manufacturing a pixel contact portion and a terminal portion in the active matrix substrate 200.

FIG. 7 is a schematic plan-view diagram illustrating an example of an active matrix substrate 700 according to a third embodiment.

FIG. 8 is a cross-sectional diagram of a crystalline silicon TFT 710A and an oxide semiconductor TFT 710B in an active matrix substrate 700.

FIGS. 9(a) to 9(f) are process-related cross-sectional diagrams, each for describing a method of forming a pixel contact portion and a terminal portion in an active matrix substrate that is a reference example.

FIG. 10 is an enlarged cross-sectional diagram schematically illustrating a portion of the pixel contact hole in the active matrix substrate that is the reference example.

FIGS. 11(a) and 11(b) are diagrams, each illustrating a SEM image and a cross-sectional SEM image that result from upward obliquely capturing an opening portion in a multi-layered passivation film, in which a notched portion 28 occurs.

### DESCRIPTION OF EMBODIMENTS

The knowledge that was found as a result of the research by the present inventor will be described below.

In a case where an active matrix substrate finds application in liquid crystal display devices that operate in an FFS mode, for example, an organic insulating layer, a common electrode, a dielectric layer, and a pixel electrode are provided in this order on a passivation film. As the dielectric layer, for example, a silicon nitride layer that has a high dielectric constant can be used. In this active matrix substrate, a contact hole (a pixel contact hole) through which a drain electrode of an oxide semiconductor TFT is exposed is formed in the dielectric layer, the organic insulating layer, and the passivation film. The pixel electrode is connected to the drain electrode in the pixel contact hole. In the present specification, a connection portion that connects between the pixel electrode and the drain electrode with the pixel contact hole in between is referred to as “pixel contact portion”.

In a process of manufacturing an active matrix substrate in the related art, when the pixel contact hole is formed, the dielectric layer and the passivation film is etched using the same mask (refer to PTL 1).

However, as a result of the research by the present inventor, it was found that, when a multi-layered passivation film that includes a silicon oxide (SiO₂) layer and a silicon nitride (SiNx) layer was used as the passivation film, a recessed portion (a notched portion) occurred in a side wall (more specifically, an end surface of the multi-layered passivation film that constitutes the pixel contact hole) of the pixel contact hole. An example where the notched portion occurs will be described below with reference to the drawings.

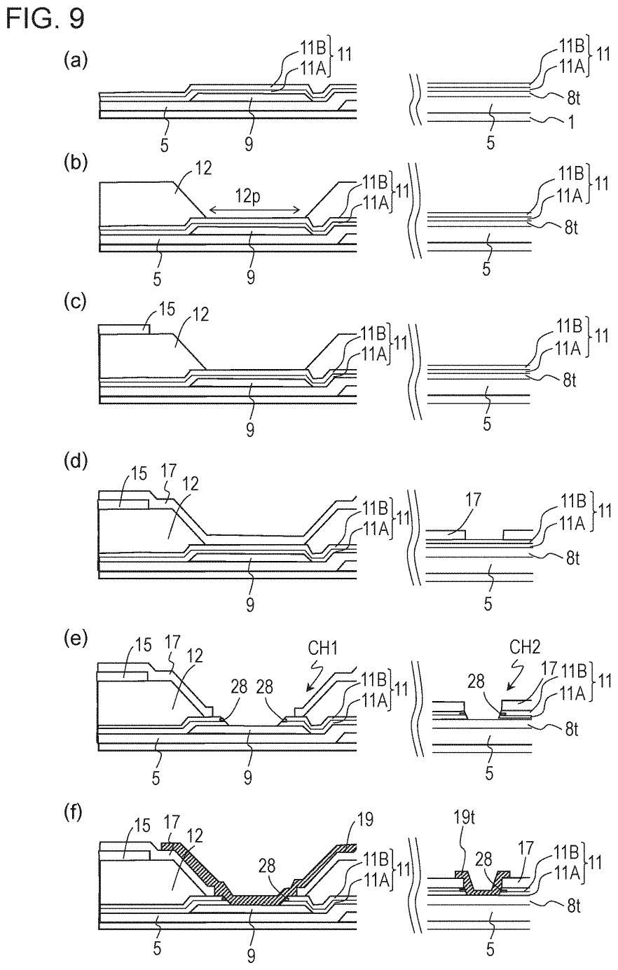

FIGS. 9(a) to 9(f) are process-related cross-sectional diagrams, each for describing a method of forming the pixel contact portion in an active matrix substrate that is a reference example. In the reference example, as described above, the passivation film and the dielectric layer are patterned using the same mask. Furthermore, a terminal portion can also be formed on a substrate by a process that is common to the terminal portion and the pixel contact portion. Because of this, a method of forming the terminal portion is illustrated as well.

First, as illustrated in FIG. 9(a), an oxide semiconductor TFT that includes a gate electrode (not illustrated), a gate insulating layer 5, an oxide semiconductor layer (not illustrated), a source electrode (not illustrated), and a drain electrode 9, and an inorganic insulating layer (a passivation film) 11 that covers the oxide semiconductor TFT are formed on a substrate 1. The inorganic insulating layer 11 is a multi-layered film of which a lower layer is a silicon oxide layer 11A and of which an upper layer is a silicon nitride layer 11B. In a terminal-portion formation area, the gate insulating layer 5 extends, and a source connection portion 8t and the inorganic insulating layer 11 that are formed the same conductive film as the source and drain electrodes are formed on the gate insulating layer 5.

Subsequently, as illustrated in FIG. 9(b), an organic insulating layer 12 is formed on the inorganic insulating layer 11 and patterning is performed on the organic insulating layer 12. Accordingly, an opening portion 12p that constitutes the pixel contact hole is formed in the organic insulating layer 12. The organic insulating layer 12 is not formed in the terminal-portion formation area.

Subsequently, as illustrated in FIG. 9(c), a common electrode (not illustrated) 15 is formed on the organic insulating layer 12. Thereafter, as illustrated in FIG. 9(d), a dielectric layer 17 is formed on the common electrode 15, on the organic insulating layer 12, and within the opening portion 12p.

Thereafter, a resist mask (not illustrated) on the dielectric layer 17, and patterning of the dielectric layer 17 and the inorganic insulating layer 11 with the resist mask as an etching mask. Specifically, first, the dielectric layer 17 and the silicon nitride layer 11B are etched using SF₆-based gas (etching time: for example, 30 to 50 sec). Thereafter, the silicon oxide layer 11A is etched using CF₄-based gas (etching time: for example, 250 to 350 sec). In this manner, as illustrated in FIG. 9(e), not only is formed a pixel contact hole CH1 through which a drain electrode 9 is exposed, but a terminal-portion contact hole CH2 through which the source connection portion 8t is exposed is also formed in the terminal-portion formation area. It is noted that an opening portion in the dielectric layer 17 may intersect an opening portion in the organic insulating layer 12 when viewed from a direction normal to the substrate 1. In this case, a portion of the inorganic insulating layer 11 is patterned with a dielectric layer 12 as a mask.

Subsequently, as illustrated in FIG. 9(f), not only is formed a pixel electrode 19 on the dielectric layer 17 and within the pixel contact hole CH1, but an upper connection portion 19t is also formed on the dielectric layer 17 and within the terminal-portion contact hole CH2. In this manner, the pixel contact portion and the terminal portion are formed.

In the method described above, in an etching process that is illustrated in FIG. 9(e), as described above, etching progresses at an interface between the silicon nitride layer 11B and the silicon oxide layer 11A, and thus a notched portion 28 occurs. In the same manner, the notched portion 28 can also occur in a wall surface of the terminal-portion contact hole CH2.

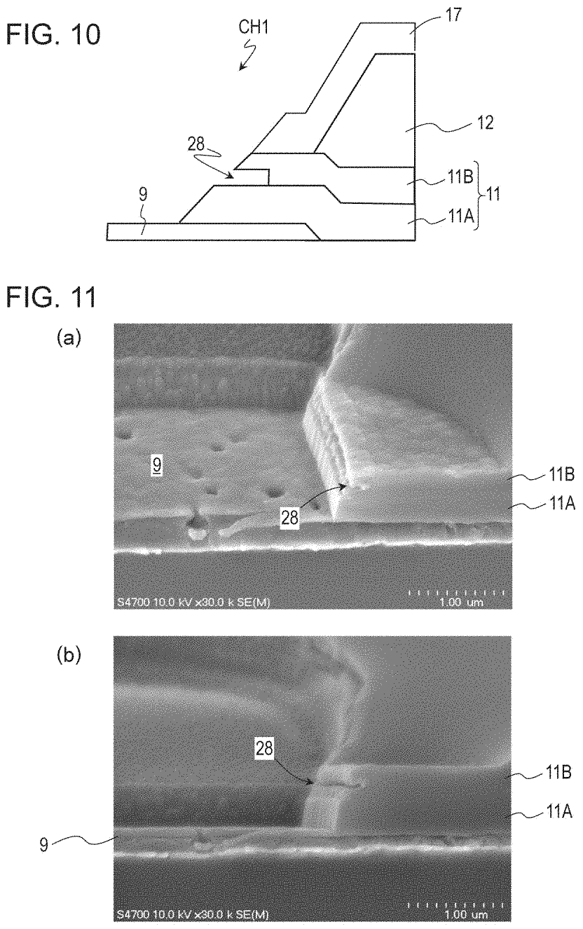

FIG. 10 is an enlarged cross-sectional diagram schematically illustrating a portion of the pixel contact hole CH1 in which the notched portion 28 occurs. The pixel contact hole CH1 is constituted by opening portions in the inorganic insulating layer 11, the organic insulating layer 12, and the dielectric layer 17. As understood from FIG. 10, the notched portion 28 is formed in an end surface of the silicon nitride layer 11B, in the vicinity of the interface between the silicon nitride layer 11B and the silicon oxide layer 11A. That is, a portion that is positioned in the vicinity of the silicon oxide layer 11A, of the end surface of the silicon nitride layer 11B that is exposed through the pixel contact hole CH1 is removed in a horizontal direction (a direction parallel to the substrate 1). As a result, the silicon nitride layer (the silicon nitride layer 11B and the dielectric layer 17) has an overhanging structure.

FIGS. 11(a) and 11(b) are diagrams, each illustrating a SEM image and a cross-sectional SEM image that result from upward obliquely capturing an opening portion in the multi-layered passivation film 11, in which the notched portion 28 occurs.

The present inventor performed close inspection to detect the cause of the occurrence of the notched portion 28. As a result, it was understood that the notched portion 28 easily occurred depending on an etching condition. For example, in a case where the etching time is lengthened when etching the silicon nitride layer 11B, etching gas is introduced into the interface between the silicon nitride layer 11B and the silicon oxide layer 11A and thus the notched portion 28 occurs. By way of speculation, because, in a process in the reference example that is illustrated in FIG. 9, the etching of the silicon nitride layer 11B and the dielectric layer 17 are etched using the same mask, there is a likelihood that the etching time for the silicon nitride layer will increase and thus that the notched portion 28 will occur.

Accordingly, the present inventor found a structure of a new pixel contact portion in which a shape of a side wall of the pixel contact hole CH1 is possibly improved and a method of forming the new pixel contact portion, and reduced the invention in the present application to practice. In an embodiment of the invention in the specification, the silicon nitride layer 11B and the dielectric layer 17 are individually patterned. Accordingly, the occurrence of the notched portion 28 is suppressed. Furthermore, by using the dielectric layer 17 and the organic insulating layer 12, it is possible that the coatability of the pixel electrode within the pixel contact hole CH1 is further increased.

### First Embodiment

An active matrix substrate according to a first embodiment will be described below with reference to the drawings. The active matrix substrate according to the embodiment of the present invention, for example, can find application in liquid crystal display devices that operate in an operation mode in compliance with transverse electric field methods such as FFS and IPS.

The active matrix substrate according to the present embodiment will be described below with reference to the drawings, taking as an example an active matrix substrate that finds application in display devices that operate in the FFS mode. The FFS mode is a mode in compliance with the transverse electric field method in which a pair of electrodes is provided on one substrate and in which an electric field is applied to a liquid crystal molecule in a direction (a horizontal direction) parallel to a substrate surface.

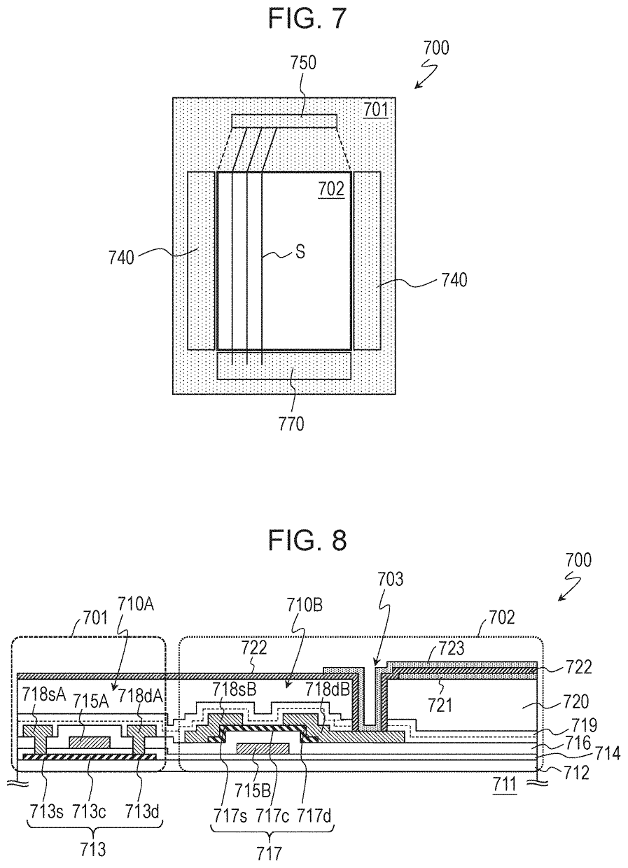

The active matrix substrate has a display area that includes multiple pixel areas and an area (a non-display area) other than the display area (refer to FIG. 7). The “pixel area” is an area that corresponds to a pixel in a display device, and, in some cases, is also referred simply to “pixel” in the present specification. Multiple gate bus lines and multiple source bus lines are formed in the display area, and each of the areas that are defined by these wiring lines is “pixel area”. Multiple pixel areas are arranged in matrix form.

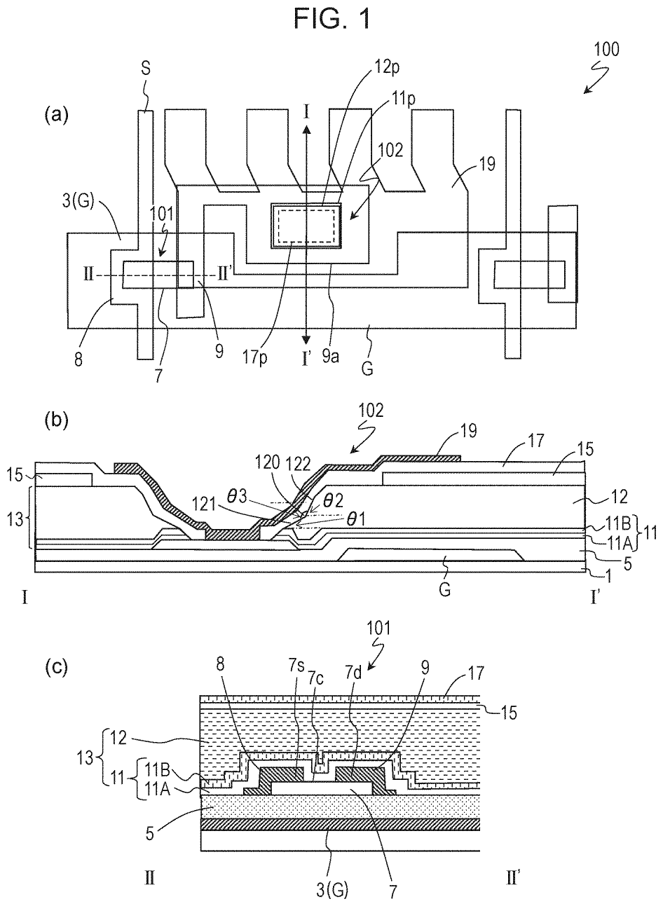

FIG. 1(a) is a schematic plan-view diagram illustrating a portion of one pixel area in an active matrix substrate 100 according to the present embodiment. FIGS. 1(b) and 1(c) are schematic cross-sectional diagrams, each illustrating an example of a pixel contact portion 102 and an oxide semiconductor TFT (hereinafter referred to as “TFT” for short) 101 in the active matrix substrate 100. FIG. 1(b) illustrates a structure of a cross-section taken along line I-I′ in FIG. 1(a). FIG. 1(c) illustrates a structure of a cross-section taken along line II-II′ in FIG. 1(a).

Each of the pixel areas has the TFT 101, a gate bus line G, a source bus line S, the pixel electrode 19, and the common electrode 15. The TFT 101 and the pixel electrode 19 are electrically connected to each other in the pixel contact portion 102.

As illustrated in FIG. 1(c), the TFT 101 is an oxide semiconductor TFT of which an active layer is an oxide semiconductor layer. The TFT 101 includes a gate electrode 3, an oxide semiconductor layer 7, the gate insulating layer 5 that is positioned between the oxide semiconductor layer 7 and the gate electrode 3, and a source electrode 8 and the drain electrode 9 are electrically connected to the oxide semiconductor layer 7.

In this example, the TFT 101, for example, has a bottom gate structure TFT that is of a channel etch type. The gate electrode 3 is positioned toward the substrate 1 on the oxide semiconductor layer 7. The gate insulating layer 5 covers the gate electrode 3, and the oxide semiconductor layer 7 is positioned in such a manner as to overlap the gate electrode 3 with the gate insulating layer 5 in between. Furthermore, each of the source electrode 8 and the drain electrode 9 is positioned in such a manner as to be brought into contact with an upper surface of the oxide semiconductor layer 7.

The oxide semiconductor layer 7 has a channel region 7c, and a source contact area 7s and a drain contact area 7d that are positioned to both the sides, respectively of the channel region. The source electrode 8 is formed in such a manner as to be brought into contact with the source contact area 7s, and the drain electrode 9 is formed in such a manner as to be brought into contact with the drain contact area 7d. In the present specification, the “channel region 7c” is positioned a portion that is between the source contact area 7s and the drain contact area 7d and in which a channel is formed, of the oxide semiconductor layer 7, when viewed from the direction normal to the substrate 1.

The gate electrode 3 of the TFT 101 is electrically connected to the gate bus line G. In this example, the gate electrode 3 and the gate bus line G are integrally formed into one piece, that is, the gate electrode 3 is a portion of the gate bus line G. The source electrode 8 is electrically connected to the source bus line S. In this example, the source electrode 8 and the source bus line S are integrally formed into one piece. The drain electrode 9 extends up to the pixel contact portion 102 and, in the pixel contact portion 102, is electrically connected to the pixel electrode 19. In some cases, a portion 9a that is positioned in the pixel contact portion 102, of the drain electrode 9 is referred to as “drain electrode connection portion”.

The TFT 101 is covered with an inter-layer insulating layer 13 that includes the inorganic insulating layer (the passivation film) 11 and the organic insulating layer 12 that is formed on the inorganic insulating layer 11. The inorganic insulating layer 11 has a multi-layered structure that includes the silicon oxide layer 11A and the silicon nitride layer 11B that is formed on the silicon oxide layer 11A. The silicon oxide layer 11A may be a layer that contains silicon oxide (SiOx, for example, SiO₂) as a main component, and may include impurities or the like other than silicon oxide. The silicon nitride layer 11B may be a layer that primarily contains silicon nitride (SiNx), and may include impurities or the like other than silicon nitride.

In this example, the inorganic insulating layer 11 has a two-layered structure. It is noted that the inorganic insulating layer 11 may include the silicon oxide layer 11A and the silicon nitride layer 11B and may have three- or greater-layered structure. It is preferable that the silicon oxide layer 11A is brought into contact with the oxide semiconductor layer 7. Accordingly, oxygen that is contained in the silicon oxide layer 11A can efficiently make up for oxygen deficiency that occurs in the oxide semiconductor layer 7. Because of this, a reduction in resistance due to the oxygen deficiency in the oxide semiconductor layer 7 can be suppressed.

The thickness of the inorganic insulating layer 11 is not particularly limited, but, for example, is equal to or greater than 50 nm and is equal to or smaller than 700 nm. The thickness of the silicon oxide layer 11A of the inorganic insulating layer 11, for example, is equal to or greater than 50 nm and is equal to or smaller than 400 nm. If the thickness is equal to or greater than 50 nm, the oxygen deficiency that occurs in the oxide semiconductor layer 7 can be more effectively made up for. If the thickness is equal to or smaller than 400 nm, an increase in the thickness of the inorganic insulating layer 11 can be suppressed. The thickness of the silicon nitride layer 11B, for example, is equal to or greater than 20 nm and is equal to or smaller than 300 nm. If the thickness is equal to or greater than 20 nm, penetration of water or impurities into the oxide semiconductor layer 7 of the TFT 101 can be more effectively suppressed. If the thickness is equal to or smaller than 300 nm, an increase in the thickness of the inorganic insulating layer 11 can be suppressed. It is preferable that the thickness of the silicon oxide layer 11A is greater than the thickness of the silicon nitride layer 11B. Accordingly, hydrogen that flows out of the silicon nitride layer 11B can be more reliably blocked in the silicon oxide layer 11A.

The organic insulating layer 12 is thicker than the inorganic insulating layer 11, and the thickness thereof, if example, is equal to or greater than 1 μm and is equal to or smaller than 4 μm. The organic insulating layer 12 is used for flattening a surface of an upper layer of the TFT 101, reducing an electrostatic capacitor that is formed between the pixel electrode 19 and the source bus line S and the like, and so on. A material of the organic insulating layer 12 is not particularly limited. For example, a positive-type photosensitive resin film is can be used as the organic insulating layer 12.

The common electrode 15 is provided on the inter-layer insulating layer 13. The pixel electrode 19 that is positioned with the dielectric layer 17 in between is provided on the common electrode 15. The dielectric layer 17 is a silicon nitride layer that primarily contains silicon nitride which has a high dielectric constant. The thickness of the dielectric layer 17 is not particularly limited, but, for example, is equal to or greater than 50 nm and is equal to or smaller than 700 nm. The pixel electrode 19 is separated from every pixel and has a slit or a notched portion in every pixel. On the other hand, the common electrode 15 may be separated from every pixel. In this example, the common electrode 15 may be formed over all portions of the display area, except for an area that is positioned on the pixel contact portion 102. This electrode structure is disclosed, for example, in International Publication No. 2012/086513. For reference, the entire contents of International Publication No. 2012/086513 are incorporated in the present specification by reference.

Subsequently, a structure of the pixel contact portion 102 is described with reference to FIG. 1(b).

In the pixel contact portion 102, the pixel contact hole CH1 is formed in the inter-layer insulating layer 13 and the dielectric layer 17. The pixel electrode 19 is positioned on the dielectric layer 17 and within the pixel contact hole CH1 and, within the pixel contact hole CH1, is brought into direct contact with a drain electrode connection portion 9a. The pixel contact hole CH1 is configured with a first opening portion 11p in the inorganic insulating layer 11, a second opening portion 12p in the organic insulating layer 12, and a third opening portion 17p in the dielectric layer 17.

In the present embodiment, an inclination angle of a flank surface in the second opening portion 12p in the organic insulating layer 12 changes discontinuously on the way, and is smaller in a lower portion (toward the substrate 1) of the second opening portion 12p than in an upper portion thereof. A flank surface of the second opening portion 12p, as illustrated, includes a first portion 121 that is inclined at a first angle θ1 with respect to a surface of the substrate 1, a second portion 122 that is positioned above the first portion 121 and that is inclined at a second angle θ2 greater than the first angle, with respect to the surface of the substrate 1, and a border 120 that is positioned between the first portion 121 and the second portion 122 and of which an inclination angle with respect to the substrate 1 discontinuously changes. This second opening portion 12p, for example, is formed by a process that will be described below. The first portion 121 in the flank surface of the second opening portion 12p and a flank surface of the first opening portion 11p are aligned (that is, are patterned using the same mask). The dielectric layer 17 is formed on the flank surfaces of the first opening portion 11p and the second opening portion 12p.

As illustrated in FIG. 1(a), due to a tapered shape, the first opening portion 11p is positioned more inward than the second opening portion 12p when the pixel contact hole CH 1 is viewed from the direction normal to the substrate 1, but peripheral edges of the first opening portion 11p and the second opening portion 12p are approximately aligned. The third opening portion 17p may be positioned inside of the first opening portion 11p and the second opening portion 12p. In other words, the dielectric layer 17 may cover the entire flank surface of each of the first opening portion 11p and the second opening portion 12p and an end portion thereof may be brought into contact with the drain electrode connection portion 9a. The drain electrode connection portion 9a is exposed in a portion in which the third opening portion 17p in the dielectric layer 17, the first opening portion 11p, and the second opening portion 12p overlap when viewed from the direction normal to the substrate 1.

In the pixel contact portion 102 according to the present embodiment, due to a shape of the flank surface of the second opening portion 12p, an inclination angle of the pixel contact hole CH1 is small in the downward direction. Therefore, disconnection of the pixel electrode 19, which is caused by step, can be suppressed from occurring on the side wall of the pixel contact hole CH1, and it is possible that coverage of the pixel electrode 19 is increased. It is preferable that the entire flank surface of each of the first opening portion 11p and of the second opening portion 12p is covered with the dielectric layer 17. Accordingly, a stepped shape that occurs the border 120 can be reduced, and because of this, the coverage of the pixel electrode 19 can be further improved.

An inclination angle (a second angle) 02 of the second portion 122 on the flank surface of the second opening portion 12p may be greater than an inclination angle (a first angle) 01 of the first portion 121, and is not particularly limited. However, the inclination angle θ2 approaches 90°, it is difficult that an end portion of the resist mask is reliably positioned on the flank surface thereof in a manufacturing process. The inclination angle θ2, for example, is equal to or smaller than 80°, preferably, is equal to or smaller than 70°. On the other hand, the inclination angle θ1 may be smaller than the inclination angle θ2 and is not particularly limited. In order to increase the coatability of the pixel electrode 19 more effectively, it is preferable that an angle θ3 that the first portion 121 and the second portion 122 in the border 120 make with respect to each other, for example, is equal to or greater than 120° and is equal to or smaller than 170°. It is more preferable that the angle θ3 is equal to or greater than 140° and is equal to or smaller 170°. There is a concern that when the angle θ3 is less than 120°, due to the stepped shape in the vicinity of the border 120, the coatability of the pixel electrode 19 will decrease. When the angle θ3 exceeds 170°, an effect of changing the inclination angle decreases. The angle θ3 is determined by a difference dθ (=θ2−θ1) between the inclination angles θ1 and θ2. In order for the angle θ3 to fall within the range described range, the inclination angles θ1 and θ2 of the first and second portions 121 and 122 may be controlled in such a manner that the difference dθ between the inclination angles, for example, is equal to or smaller than 60° and is equal to or greater than 10°, preferably, is equal to or smaller than 40° and is equal to or greater than 10°.

<Method of Manufacturing the Active Matrix Substrate 100>

An example of a method of manufacturing the active matrix substrate 100 will be described below with reference with the drawings.

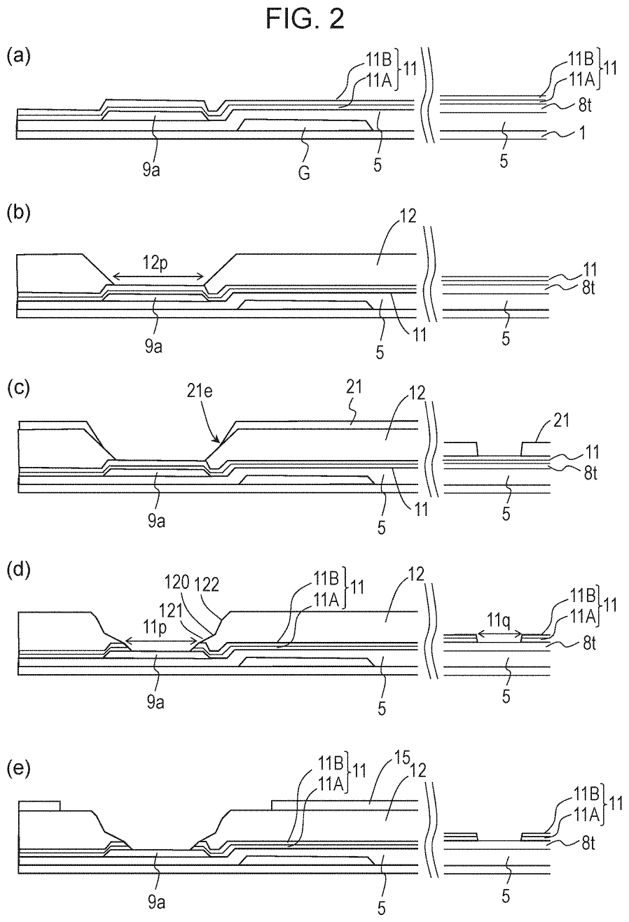

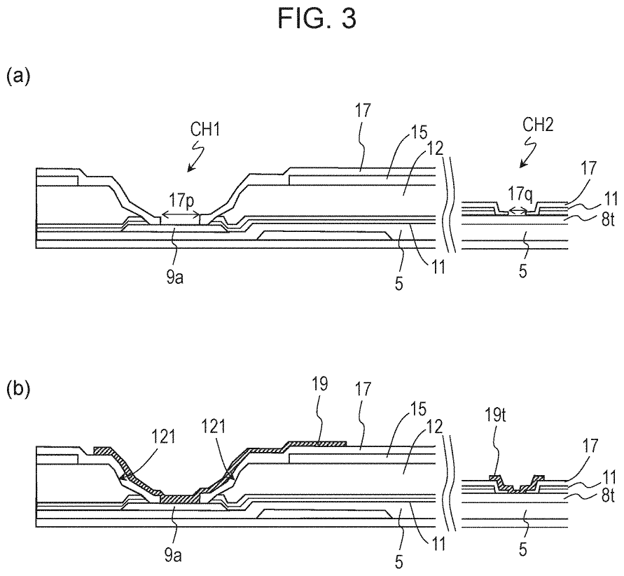

FIGS. 2(a) to 2(e), 3(a), and 3(b) are process-related cross-sectional diagrams, each illustrating an example of the method of manufacturing the pixel contact portion and the terminal portion in the active matrix substrate 100. In these figures, a pixel contact portion formation area in each pixel area of the active matrix substrate 100 and the terminal-portion formation area in the non-display area of the active matrix substrate 100 are illustrated. The terminal portion, for example, is provided in order to connect the source bus line and an external wiring line and can be formed by a process that is common to the terminal portion and the pixel contact portion 102.

First, as illustrated in FIG. 2(a), a layer (hereinafter referred to as “gate metal layer”) that includes the gate electrode (not illustrated) and the gate bus line G gate electrode (not illustrated) are formed on the substrate 1.

As the substrate 1, for example, a glass substrate, a silicon substrate, a plastic substrate (a resin substrate) that has a heat-resisting property, or the like can be used.

For example, the gate wiring line metal film (the thickness thereof, for example, is equal to or greater than 50 nm and is equal to or smaller than 500 nm) is formed on the substrate (for example, a glass substrate) 1 using a sputtering method, and the gate wiring line metal film is patterned. Thus, the gate metal layer is formed. As the gate wiring line metal film, for example, a multi-layered film (a W/TaN film) of which an upper layer is a W film having a thickness of 300 nm and of which a lower layer is a TaN film having a thickness of 20 nm. It is noted that a material of the gate wiring line metal film is not particularly limited. A film that contains a metal, such as aluminum (Al), tungsten (W), molybdenum (Mo), tantalum (Ta), chrome (Cr), titanium (Ti), or copper (Cu), an alloy of these, or metal nitride of these can be suitably used.

Subsequently, the gate insulating layer 5 is formed on the gate electrode and the gate bus line G. The gate insulating layer 5 can be formed using a CVD method or the like. As the gate insulating layer 5, a silicon oxide (SiO₂) layer, a silicon nitride (SiNx) layer, a silicon-oxide-nitride (SiOxNy; x>Y) layer, a silicon nitride oxide (SiNxOy; x>y) layer, or the like can be suitably used. The gate insulating layer 5 may have a multi-layered structure. For example, a silicon nitride layer, a silicon nitride oxide layer, or the like may be formed toward the substrate (the lower layer) in order to prevent impurities or the like from being diffused from the substrate 1, and a silicon oxide layer, a silicon-oxide-nitride layer, or the like may be formed on the above-described layer (the upper layer) to ensure the insulation. At this point, a multi-layered film of which an upper layer is a SiO₂ film having a thickness of 50 nm and of which a lower layer is a SiNx layer having a thickness of 300 nm. In this manner, when an insulating layer (for example, an oxide layer, such as an SiO₂ layer) that contains oxygen is used as an uppermost layer (that is, a layer that is brought into contact with an oxide semiconductor layer) of the gate insulating layer 5, in a case where the oxygen deficiency occurs in the oxide semiconductor layer 7, it is possible that oxygen which is contained in the oxide layer makes up for the oxygen deficiency. Because of this, the oxygen deficiency in the oxide semiconductor layer 7 can be reduced.

Thereafter, although not illustrated, an oxide semiconductor layer is formed on the gate insulating layer 5. For example, an oxide semiconductor film (the thickness thereof, for example, is equal to or greater than 30 nm and is equal to or smaller than 200 nm) is formed on the gate insulating layer 5 and this oxide semiconductor film is patterned. Thus, the oxide semiconductor layer is formed.

Subsequently, for example, a source wiring line metal film (the thickness thereof, for example, is equal to or greater than 50 nm and is equal to or smaller than 500 nm) is formed on the gate insulating layer 5 and the oxide semiconductor layer using the sputtering method, and this source wiring line metal film is patterned. Accordingly, not only are formed the source bus line (not illustrated) and source and drain electrodes (not illustrated), but the drain electrode connection portion 9a and the source connection portion 8t are also formed in the pixel contact portion formation area and the terminal-portion formation area, respectively. The source connection portion 8t, for example, is electrically connected to the connector source bus line or gate bus line. A layer that is formed from the source wiring line metal film is referred to as “source metal layer”. As a source conductive film, a film that contains a metal, such as aluminum (Al), tungsten (W), molybdenum (Mo), tantalum (Ta), chrome (Cr), titanium (Ti), or copper (Cu), an alloy of these, or a metal nitride of these can be suitably used. Furthermore, a multi-layered film that results from stacking these multiple films may be used. At this point, as the source wiring line metal film, for example, a multi-layered film is formed that results from stacking a Ti film (the thickness: 30 nm), a Al or Cu film (the thickness: 300 nm), and a Ti film (the thickness: 50 nm) one on top of another in this order, starting from the oxide semiconductor layer side.

The source electrode is positioned in such a manner as to be brought into contact with a source contact area of the oxide semiconductor layer, and the drain electrode is positioned in such a manner as to be brought into contact with a drain contact area of the oxide semiconductor layer. A portion that is positioned between the source electrode and the drain electrode, of the oxide semiconductor layer is the channel region. Thereafter, oxidation processing, for example, plasma processing that uses N₂O gas may be performed on the channel region of the oxide semiconductor layer. In this manner, the TFT 101 (not illustrated) is obtained.

Next, the inorganic insulating layer 11 is formed on the gate insulating layer 5 and the source metal layer in such a manner as cover the TFT 101. At this point, the silicon oxide layer 11A (the thickness thereof, for example, is 100 nm) and the silicon nitride layer 11B (the thickness thereof, for example, 200 nm) are formed in this order, for example, using the CVD method. A temperature at which the inorganic insulating layer 11, for example, is equal to or higher than 200° C. and is equal to or lower than 300° C.

In the terminal-portion formation area, the gate insulating layer 5, the source connection portion 8t, the inorganic insulating layer 11 are formed, by the processes described above, on the substrate 1.

Subsequently, as illustrated in FIG. 2(b), the organic insulating layer 12 (the thickness thereof, for example, is 1 to 3 μm, preferably, 2 to 3 μm) is formed on the inorganic insulating layer 11. As the organic insulating layer 12, an organic insulating film may be formed that contains a photosensitive resin material. Subsequently, patterning of the organic insulating layer 12 is performed by a photolithography process. Accordingly, the second opening portion 12p through which a portion that is positioned in the drain electrode connection portion 9a, of the inorganic insulating layer 11 is exposed is formed on the organic insulating layer 12. Furthermore, a portion that is positioned in the terminal-portion formation area, of the organic insulating layer 12 is removed.

Subsequently, as illustrated in FIG. 2(c), a resist mask 21 is formed on the inorganic insulating layer 11 and the organic insulating layer 12. In the pixel contact portion formation area, the resist mask 21 covers an upper surface of the organic insulating layer 12 and has an opening through which a portion that is positioned in the drain electrode connection portion 9a, of the inorganic insulating layer 11 is exposed. In the present embodiment, an end portion 21e of the opening in the resist mask 21 is patterned in such as to be positioned on a flank surface of the organic insulating layer 12. The end portion 21e, for example, may be positioned upward at a height that is greater than half of the thickness of the organic insulating layer 12. On the other hand, in the terminal-portion formation area, the resist mask 21 has an opening through which a portion of the inorganic insulating layer 11 is exposed.

Subsequently, as illustrated in FIG. 2(d), the patterning of the inorganic insulating layer 11 is performed with the resist mask 21 as the etching mask. In the present embodiment, first, for example, etching of the silicon nitride layer 11B using SF₆-based gas (etching time: for example, 30 to 40 sec). Thereafter, subsequently, etching of the silicon oxide layer 11A using CF₄-based gas (etching time: for example, 250 to 250 sec). Accordingly, not only is formed the first opening portion 11p through which a portion of the drain electrode connection portion 9a is exposed, in the pixel contact portion formation area, but a fourth opening portion 11q through which a portion of the source connection portion 8t is exposed is also formed in the terminal-portion formation area. Thereafter, the resist mask 21 removed.

In a process of patterning the inorganic insulating layer 11, a surface layer of a portion that is exposed by the resist mask 21, of the organic insulating layer 12 is also removed. As a result, the border 120 in which an inclination angle of the flank surface of the organic insulating layer 12 discontinuously changes is formed to be positioned more downward than the resist mask 21. A portion that is positioned to be more upward than the border 120, of the flank surface of the organic insulating layer 12 is the second portion 122, and a portion that is positioned to be more downward than the border 120 is the first portion 121 that has a smaller inclination angle than the second portion 122.

Subsequently, as illustrated in FIG. 2(e), a first transparent conductive film (the thickness thereof, for example, is equal to or greater than 50 nm and is equal to or smaller than 200 nm) is formed on the organic insulating layer 12 and within the opening portions 12p and 11p. Subsequently, by patterning the first transparent conductive film, the common electrode 15 is formed in the display area. As the first transparent conductive film, for example, an indium and tin oxide (ITO) film, an indium and zinc oxide (In—Zn—O-based oxide) film, a zinc oxide film (ZnO film), or the like can be used.

Subsequently, as illustrated in FIG. 3(a), the dielectric layer 17 is formed in such a manner as to cover the common electrode 15. As the dielectric layer 17, a silicon nitride (SiNx) film, a silicon oxide (SiOx) film, a silicon oxide nitride (SiOxNy; x>Y) film, a silicon nitride oxide (SiNxOy; x>y) film, or the like can be suitably used. At this point, as the dielectric layer 17, a silicon nitride film (the thickness thereof: for example, 200 nm) is used from the perspective of the dielectric constant and the insulation.

Thereafter, the resist mask that is not illustrated is formed, and the resist mask is etched, thereby performing etching the dielectric layer 17. Accordingly, not only is formed the third opening portion 17p through which a portion of the drain electrode connection portion 9a is exposed is formed, in the pixel contact portion formation area, but a fifth opening portion 17q through which a portion of the source connection portion 8t is exposed is also formed in the terminal-portion formation area. In this manner, the pixel contact hole CH1 is formed in the pixel contact portion formation area, and the terminal-portion contact hole CH2 is formed in the terminal-portion formation area.

It is preferable that the dielectric layer 17 covers the entire side wall of each of the second opening portion 12p and the first opening portion 11p. Accordingly, the coatability of the pixel electrode that is formed within the pixel contact hole CH1 can be increased more effectively. Furthermore, it is preferable that the dielectric layer 17 covers the entire side wall of the fourth opening portion 11q. Accordingly, the coatability of a transparent connection portion that is formed within the terminal-portion contact hole CH2 can be increased.

Subsequently, as illustrated in FIG. 3(b), a second transparent conductive film is formed on the dielectric layer 17, within the pixel contact hole CH1 and within the terminal-portion contact hole CH2, and this second transparent conductive film is patterned. Accordingly, the pixel electrode 19 that is brought into contact with the drain electrode connection portion 9a within the pixel contact hole CH1 and the upper connection portion 19t that is brought into contact with the source connection portion 8t within the terminal-portion contact hole CH2 are obtained. The suitable material and thickness of the second transparent conductive film may be the same as those of the first transparent conductive film. In this manner, the active matrix substrate 100 is manufactured.

With the method described above, the dielectric layer 17 and the inorganic insulating layer 11 are individually patterned. Because of this, the time for which the silicon nitride layer 11B is exposed to etching gas can be shortened. Therefore, the notched portion 28 that is described above with reference to FIG. 10 can be suppressed from occurring in the silicon nitride layer 11B. Furthermore, in a state where the resist mask 21 that covers only an upper part of a tapered portion of the organic insulating layer 12, the patterning of the inorganic insulating layer 11 is performed. Accordingly, a surface layer of a lower part of the tapered portion of the organic insulating layer 12 is also etched, and an inclination angle is decreased. Therefore, a decrease in the coverage of the pixel electrode 19 can be suppressed, and an active matrix substrate that has high reliability can be realized.

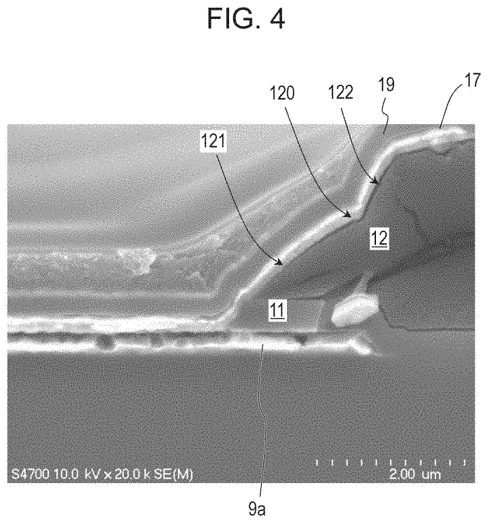

FIG. 4 is a cross-sectional diagram illustrating a pixel contact hole in the active matrix substrate 100 that is manufactured with the method described above. From FIG. 4, it is understood that the border 120 is formed on the flank surface of the organic insulating layer 12 and that the flank surface of the second opening portion 12p has a shape that is more slightly tapered. Furthermore, it is checked that the notched portion 28 as illustrated in FIG. 10 does not occur in the side wall of the first opening portion 11p.

It is noted that, as a method of individually patterning the inorganic insulating layer 11 and the dielectric layer 17, in addition to the method described above, it is also considered that the patterning of the inorganic insulating layer 11 is performed with the organic insulating layer 12 as a mask. However, in a case where the organic insulating layer 12 is not formed in the non-display area, the organic insulating layer 12 is not present in the terminal-portion formation area. For this reason, in the patterning with the organic insulating layer 12 as the mask, the fourth opening portion 11q cannot be formed in the inorganic insulating layer 11 in the terminal-portion formation area (the inorganic insulating layer 11 in the non-display area is all removed). Furthermore, in a case where a patterning process in which the organic insulating layer 12 serves as the mask, a tapered shape of the organic insulating layer 12 is maintained as when the organic insulating layer 12 is formed. In contrast to this, in the present embodiment, the patterning of the inorganic insulating layer 11 is performed using the resist mask 21 that is formed on the organic insulating layer 12. Because of this, the fourth opening portion 11q can also be formed in the terminal-portion formation area. More precisely, the terminal-portion contact hole CH2 can also be formed using a process that is common to the terminal-portion contact hole CH2 and the pixel contact hole CH1. Furthermore, by discontinuously changing the inclination angle of the flank surface of the organic insulating layer 12 on the way, the tapered shape of the organic insulating layer 12 can be controlled. Therefore, it is possible that the coatability of the pixel electrode 19 is further increased.

<TFT Structure>

A structure of a pixel TFT that is used in the active matrix substrate according to the present embodiment is not limited to a structure that is illustrated in FIG. 1. The TFT 101 that is illustrated in FIG. 1 has a top contact structure in which the source and drain electrodes are brought into contact with an upper surface of the semiconductor layer, but may have a bottom contact structure in which the source and drain electrodes are brought into contact with a lower surface of the semiconductor layer.

Furthermore, a TFT according to the present embodiment may have a channel etch structure and may have an etch stop structure. In a channel etch type TFT, as illustrated in FIG. 1, end portion lower surfaces that are toward the channel, of the source electrode and the drain electrode, are arranged in such a manner as to be brought into contact with an upper surface of the oxide semiconductor layer, without an etch stop layer being formed on the channel region. For example, a conductive film for the source and drain electrodes is formed on the oxide semiconductor layer, and separation of a source and a drain is performed. Thus, the channel etch type TFT is formed. In some cases, in a process of separating the source and the drain, a surface portion of the channel region is etched.

In an etch stop type TFT, the etch stop layer is formed on the channel region. The lower end lower surfaces that are toward the channel, of the source and drain electrodes, for example, are positioned on the etch stop layer. For example, the etch stop layer that covers a portion that is a channel region, of the oxide semiconductor layer is formed, and then the conductive film for the source and drain electrodes is formed on the oxide semiconductor layer and the etch stop layer and the separation of the source and the drain is performed. Thus, the etch stop type TFT is formed.

The TFT 101 that is illustrated in FIG. 1 may have a bottom gate structure TFT in which the gate electrode 3 is positioned between the oxide semiconductor layer 7 and the substrate 1, but the gate electrode 3 may have a top gate structure TFT that the gate electrode 3 is positioned in a direction opposite to the substrate 1, of the oxide semiconductor layer 7.

<Oxide Semiconductor>

The oxide semiconductor that is included in the oxide semiconductor layer 7 may be an amorphous oxide semiconductor and may be a crystalline oxide semiconductor that has a crystalline portion. As the crystalline oxide semiconductor, a polycrystalline oxide semiconductor, a micro-crystalline oxide semiconductor, a crystalline oxide semiconductor in which a c-axis aligns approximately vertically with a layer surface, or the like is given.

The oxide semiconductor layer 7 may have a multi-layered structure. In a case where the oxide semiconductor layer 7 has the multi-layered structure, the oxide semiconductor layer 7 may include a non-crystalline oxide semiconductor layer and a crystalline oxide semiconductor layer. Alternatively, multiple crystalline oxide semiconductor layers that have different crystalline structures may be included. Furthermore, multiple non-crystalline oxide semiconductor layers may be included. In a case where the oxide semiconductor layer 7 has a two-layered structure that includes an upper layer and a lower layer, it is preferable that an energy gap of the oxide semiconductor that is included in the upper layer is greater than an energy gap of the oxide semiconductor that is included in the lower layer. However, in a case where a difference in the energy gap between the upper and lower layers is comparatively small, the energy gap of the oxide semiconductor in the lower layer may be greater than the energy gap of the oxide semiconductor in the upper layer.

Materials and structures of the non-crystalline oxide semiconductor and each of the crystalline oxide semiconductors described above, a film formation method, a structure of the oxide semiconductor layer that has a multi-layered structure, and the like, for example, are described in Japanese Unexamined Patent Application Publication No. 2014-007399. For reference, the entire contents of Japanese Unexamined Patent Application Publication No. 2014-007399 is incorporated in the present specification by reference.

The oxide semiconductor layer 7, for example, may include at least one type of metal element among In, Ga, and Zn. In the present embodiment, the oxide semiconductor layer 7 may include, for example, an In—Ga—Zn—O-based semiconductor (for example, oxide indium gallium zinc). The In—Ga—Zn—O-based semiconductor here is a ternary oxide material that consists of Indium (In), Gallium (Ga), and Zinc (Zn). A ratio (a composition ratio) among In, Ga, and Zn is not particularly limited. Examples of the ratio include In:Ga:Zn=2:2:1, In:Ga:Zn=1:1:1, In:Ga:Zn=1:1:2, and the like. This oxide semiconductor layer 7 can be formed from an oxide semiconductor film that contains an In—Ga—Zn—O-based semiconductor.

The In—Ga—Zn—O-based semiconductor may be amorphous and may be crystalline. A crystalline in-Ga—Zn—O-based semiconductor in which a c-axis aligns approximately vertically with a layer surface is preferable as a crystalline In—Ga—Zn—O-based semiconductor.

It is noted that a crystalline structure of the crystalline In—Ga—Zn—O-based semiconductor, for example, is disclosed in Japanese Unexamined Patent Application Publication Nos. 2014-007399, 2012-134475, and 2014-209727, which are described above, and other publications. For reference, the entire contents of Japanese Unexamined Patent present Nos. 2012-134475 and 2014-209727 are incorporated in the present specification by reference. A TFT that has an In-GA-Zn—O-based semiconductor layer has high mobility (which is more than 20 times higher than that of an a-Si TFT) and a small amount of leak electric current (which is less than one-hundredth of that of the a-Si TFT). Because of this, the TFT is suitably used as a drive TFT (for example, a TFT that is included in a drive circuit which is provided on the same substrate as a display area, in the vicinity of the display area that includes multiple pixels) and a pixel TFT (a TFT that is provided in a pixel).

The oxide semiconductor layer 7 may contain any other oxide semiconductor instead of the In—Ga—Zn—O-based semiconductor. For example, an In—Sn—Zn—O-based semiconductor (for example, In₂O₃—SnO₂—ZnO; InSnZnO) may be contained. The In—Sn—Zn—O-based semiconductor is a ternary oxide material that consists of Indium (In), Tin (Sn), and Zinc (Zn). Alternatively, the oxide semiconductor layer 7 may contain an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, Cadmium oxide (CdO), a Mg—Zn—O-based semiconductor, an In—Ga—Sn—O-based semiconductor, an In—Ga—O-based semiconductor, a Zr—In—Zn—O-based semiconductor, a Hf—In—Zn—O-based semiconductor, an Al—Ga—Zn—O-based semiconductor, a Ga—Zn—O-based semiconductor, or the like.

### Second Embodiment

An active matrix substrate according to a second embodiment will be described below with reference to the drawings. The active matrix substrate according to the present embodiment is different from that according to the first embodiment in that in the pixel contact portion, at least a portion of the flank surface of the first opening portion 11p is positioned more backward than the flank surface of the second opening portion 12p. A difference from the active matrix substrate 100 according to the first embodiment will be described below in a focused manner, and descriptions that are the same as those of the active matrix substrate 100 are omitted.

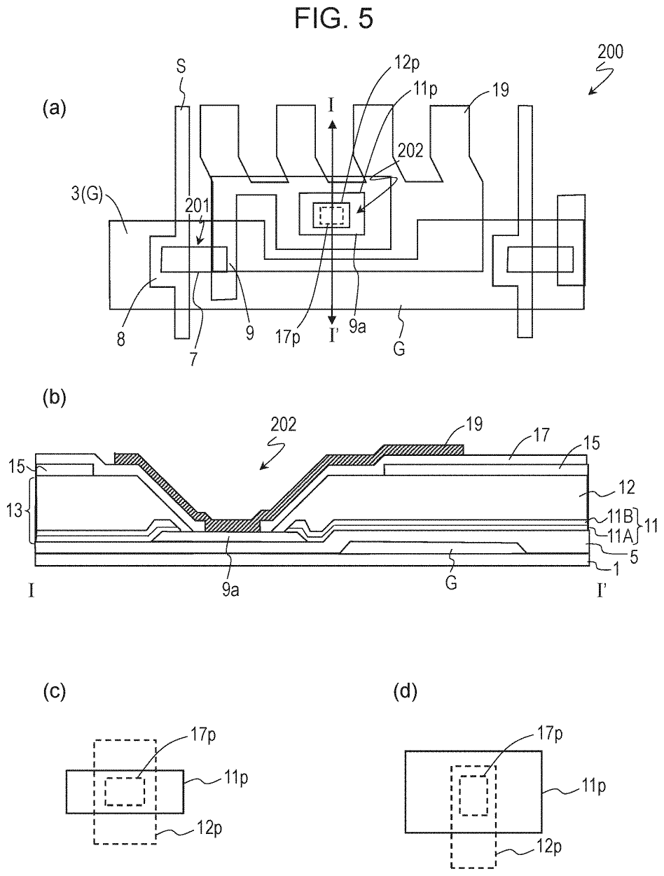

FIG. 5(a) is a schematic plan-view diagram illustrating a portion of one pixel area in an active matrix substrate 200 according to the present embodiment. FIG. 5(b) is a schematic cross-sectional diagram illustrating an example of a pixel contact portion 202 in the active matrix substrate 200, and illustrates a structure of a cross-section taken along line I-I′ in FIG. 5(a).

An oxide semiconductor TFT 201 according to the present embodiment has the same structure as the oxide semiconductor TFT 101 that is described above with reference to FIG. 1(c), and thus an illustration and a description thereof are omitted.

In the pixel contact portion 202 according to the present embodiment, as illustrated in FIG. 5(b), the pixel contact hole CH1 is formed in the inter-layer insulating layer 13 and the dielectric layer 17. The pixel electrode 19 is positioned on the dielectric layer 17 and within the pixel contact hole CH1 and, within the pixel contact hole CH1, is brought into direct contact with the drain electrode connection portion 9a.

The pixel contact hole CH1 is configured with the first opening portion 11p in the inorganic insulating layer 11, the second opening portion 12p in the organic insulating layer 12, and the third opening portion 17p in the dielectric layer 17. The organic insulating layer 12 covers the entire surface of the first opening portion 11p, and the dielectric layer 17 covers the entire flank surface of the organic insulating layer 12. An end portion of the dielectric layer 17 is brought into contact with the drain electrode connection portion 9a.

As illustrated in FIG. 5(a), when the pixel contact portion 202 is viewed from the direction normal to the substrate 1, the second opening portion 12p is positioned inside of the first opening portion 11p and the third opening portion 17p is positioned inside of the second opening portion 12p.

In the pixel contact portion 202 according to the present embodiment, the inorganic insulating layer 11 and the dielectric layer 17 are individually patterned. Because of this, the notched portion 28 (FIG. 10) does not occur in the inorganic insulating layer 11. Furthermore, because the flank surface of the first opening portion 11p is covered with both the organic insulating layer 12 and the dielectric layer 17, although the slight unevenness occurs in the flank surface of the first opening portion 11p, the slight unevenness is flattened by both the layers, and thus a shape of the pixel contact hole CH1 is not influenced. Therefore, disconnection of the pixel electrode 19, which is caused by step, can be suppressed from occurring on the side wall of the pixel contact hole CH1, and it is possible that coverage of the pixel electrode 19 is increased.

It is preferable that the dielectric layer 17 covers the entire flank surface of the organic insulating layer 12. Accordingly, when the dielectric layer 17 is etched, partial etching of a surface layer portion of the organic insulating layer 12 can be suppressed. Because of this, the tapered shape that has a small stepped shape can be formed on the side wall of the pixel contact hole CH1.

A structure of the pixel contact hole CH1 is not particularly limited to structures that are illustrated in FIGS. 5(a) and 5(b). It is preferable that in the pixel contact portion 202 according to the present embodiment, the entire flank surface of the first opening portion 11p is covered with the organic insulating layer 12, but at least a portion of the flank surface of the first opening portion 11p may be covered with the organic insulating layer 12. In other words, if only a portion of the second opening portion 12p is positioned within the first opening portion 11p when viewed from the direction normal to the substrate 1, a fixed effect is obtained. For example, the second opening portion 12p and the first opening portion 11p may orthogonally intersect each other when viewed from the direction normal to the substrate 1.

FIGS. 5(c) and 5(d) are schematic plan-view diagram, each illustrating a modification example of the pixel contact hole CH1 in the pixel contact portion 202. At this point, the first opening portion 11p, the second opening portion 12p, and the third opening portion 17p are rectangular. For example, as illustrated in FIG. 5(c), the second opening portion 12p may be positioned in such a manner as to cross the first opening portion 11p when viewed from the direction normal to the substrate 1. Alternatively, as illustrated in FIG. 5(d), the peripheral edge of the second opening portion 12p may be positioned in such a manner as to cross only one side of the peripheral edge of the first opening portion 11p when viewed from the direction normal to the substrate 1. In these cases, a portion of the flank surface of the first opening portion 11p is covered with the organic insulating layer 12, and a portion that is not covered with the organic insulating layer 12, of the flank surface of the first opening portion 11p is covered with the dielectric layer 17.

<Method of Manufacturing the Active Matrix Substrate 200>

An example of a method of manufacturing the active matrix substrate 200 will be described below with reference to the drawings.

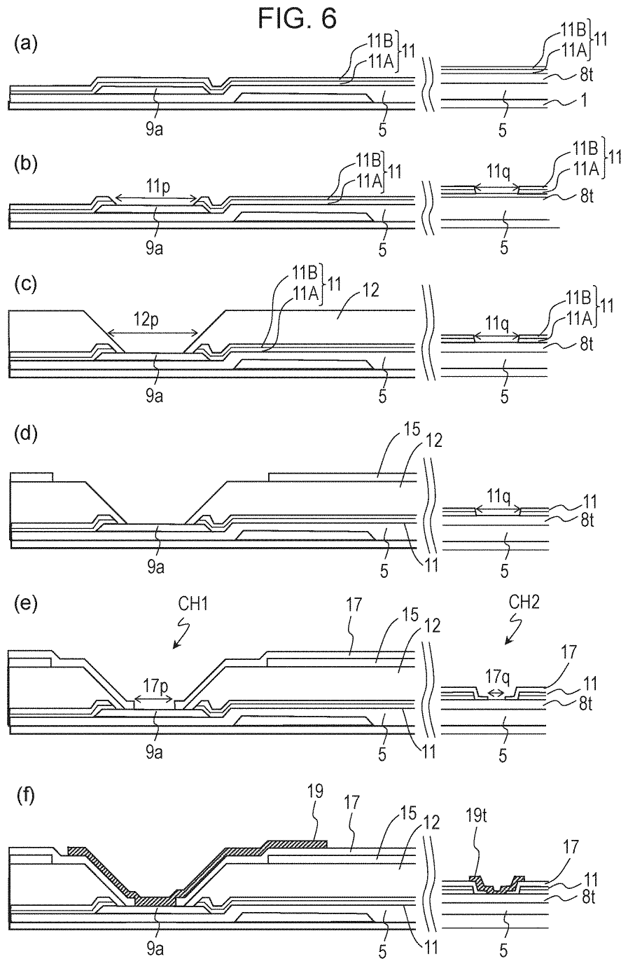

FIGS. 6(a) to 6(f) are process-related cross-sectional diagrams, each illustrating an example of the method of manufacturing the pixel contact portion and the terminal portion in the active matrix substrate 200. In these figures, the pixel contact portion formation area and the terminal-portion formation area are illustrated, and the same constituent element as in the active matrix substrate 100 is given the same reference character. A difference from the method of manufacturing the active matrix substrate 100 will be described below in a focused manner. A method of forming each layer in the active matrix substrate 200, and a material and a thickness of each layer are the same as those in the active matrix substrate 100, and thus descriptions thereof are omitted.

First, as illustrated in FIG. 6(a), a gate metal layer that includes the gate bus line G, the gate insulating layer 5, a source metal layer that includes the drain electrode connection portion 9a and the source connection portion 8t, and the inorganic insulating layer 11 are formed on the substrate 1. Process of forming these layers are the same as those which are described above with reference to FIG. 2(a).

Subsequently, the resist mask (not illustrated) is formed on the inorganic insulating layer 11, and the patterning of the inorganic insulating layer 11 is formed. Accordingly, as illustrated in FIG. 6(b), the first opening portion 11p through which a portion of the drain electrode connection portion 9a is exposed is formed in the pixel contact portion formation area. The fourth opening portion 11q through which a portion of the source connection portion 8t is exposed is formed in the terminal-portion formation area. Etching gas that is used for patterning and an etching condition may be the same as the etching gas and the etching condition that are described above with reference to FIG. 2(c).

Subsequently, as illustrated in FIG. 6(c), the organic insulating layer 12 is formed on the inorganic insulating layer 11, within the first opening portion 11p, and within the fourth opening portion 11q, and the patterning of the organic insulating layer 12 is performed by the photolithography process. Accordingly, the second opening portion 12p through which a portion of the drain electrode connection portion 9a is exposed is formed in the organic insulating layer 12. In this example, the second opening portion 12p is positioned inside of the first opening portion 11p. Therefore, in the pixel contact portion formation area, an upper surface and a flank surface (an end surface) of the first opening portion 11p are covered with the organic insulating layer 12. A portion that is positioned in the terminal-portion formation area, of the organic insulating layer 12 is removed. It is noted that, as described with reference to FIGS. 5(c) and 5(d), a portion of the flank surface of and a portion of the upper surface of the first opening portion 11p may be exposed through the second opening portion 12p.

Subsequently, as illustrated in FIG. 6(d), the common electrode 15 is formed on the organic insulating layer 12. Thereafter, as illustrated in FIG. 6(e), the dielectric layer 17 is formed in such a manner as to cover the common electrode 15 and the etching of the dielectric layer 17 is performed. Accordingly, not only is formed the third opening portion 17p through which a portion of the drain electrode connection portion 9a is exposed is formed, in the pixel contact portion formation area, but a fifth opening portion 17q through which a portion of the source connection portion 8t is exposed is also formed in the terminal-portion formation area. In this manner, the pixel contact hole CH1 is formed in the pixel contact portion formation area, and the terminal-portion contact hole CH2 is formed in the terminal-portion formation area. In this example, the dielectric layer 17 is positioned in such a manner as to cover the entire side wall of each of the second opening portion 12p and the first opening portion 11p.

Subsequently, as illustrated in FIG. 6(f), the second transparent conductive film is formed on the dielectric layer 17, within the pixel contact hole CH1, and within the terminal-portion contact hole CH2, and the second transparent conductive layer is patterned. Accordingly, the pixel electrode 19 that is brought into contact with the drain electrode connection portion 9a within the pixel contact hole CH1 and the upper connection portion 19t that is brought into contact with the source connection portion 8t within the terminal-portion contact hole CH2 are obtained. In this manner, the active matrix substrate 200 is manufactured.

With the method described above, the dielectric layer 17 and the inorganic insulating layer 11 are individually patterned. Because of this, the time for which the silicon nitride layer 11B is exposed to the etching gas can be shortened. Therefore, the notched portion 28 that is described above with reference to FIG. 10 can be suppressed from occurring in the silicon nitride layer 11B. Furthermore, after the patterning of the inorganic insulating layer 11, the organic insulating layer 12 is formed. Because of this, the unevenness that occurs in the flank surface of the first opening portion 11p can be flattened. Therefore, in the pixel contact portion, the decrease in the coverage of the pixel electrode 19 can be suppressed.

### Third Embodiment

An active matrix substrate according to a third embodiment will be described below with reference to the drawings. The active matrix substrate according to the present embodiment includes an oxide semiconductor TFT and a crystalline silicon TFT that are formed on the same substrate.

The active matrix substrate includes a TFT (a pixel TFT) in every pixel. As the pixel TFT, for example, the oxide semiconductor TFT of which an active layer is an In—Ga—Zn—O-based semiconductor film is used.

In some cases, a portion or all portions of a peripheral drive circuit are also integrally formed on the same substrate as the pixel TFT. Such an active matrix substrate is referred to as a driver monolithic active matrix substrate. In the driver monolithic active matrix substrate, the peripheral drive circuit is provided in an area (a non-display area or a frame area) other than an area (a display area) that includes multiple pixels. As a TFT (a circuit TFT) that constitutes the peripheral drive circuit, for example, a crystalline silicon TFT of which an active layer is a polycrystalline silicon film is used. In this manner, when the oxide semiconductor TFT is used as the pixel TFT and when the crystalline silicon TFT is used as the circuit TFT, it is possible that power consumption is reduced in the display area, and it is further possible that the frame area is decreased.

It is possible that the TFTs 101 and 201 and the pixel contact portions 102 and 202 that are described with reference to FIGS. 1 and 5 find application as the pixel TFTs and the pixel contact portions, respectively. This will be described below.

Next, a more specific configuration of the active matrix substrate according to the present embodiment will be described with reference to the drawings.

FIG. 7 is a schematic plan-view diagram illustrating an example of a planar structure of an active matrix substrate 700 according to the present embodiment. FIG. 8 is a cross-sectional diagram illustrating structures of cross-sections of a crystalline silicon TFT 710A (hereinafter referred to as “first thin film transistor”) and an oxide semiconductor TFT 710B (hereinafter referred to as “second thin film transistor”) in the active matrix substrate 700. It is noted that a pixel contact portion 703 has a structure that is illustrated in FIG. 1 or 5, but that a detailed structure is omitted in the drawings.

As illustrated in FIG. 7, the active matrix substrate 700 has a display area 702 that includes multiple pixels, and an area (the non-display area) other than the display area 702. The non-display area includes a drive circuit formation area 701 in which a drive circuit is provided. For example, a gate driver circuit 740, an inspection circuit 770, and the like are provided in the drive circuit formation area 701. In the display area 702, multiple gate bus lines (not illustrated) that extend in the row direction, and multiple source bus lines S that extend in the column direction are formed. Although not illustrated, each pixel is defined by the gate bus line and the source bus line S. Each of the gate bus lines is connected to each terminal of a gate driver circuit. Each of the source bus line S is connected to each terminal of a driver IC 750 that is mounted in the active matrix substrate 700.

As illustrated in FIG. 8, in the active matrix substrate 700, a second thin film transistor 710B is formed, as a pixel TFT, in each pixel in the display area 702, and a first thin film transistor 710A is formed, as a circuit TFT, in the drive circuit formation area 701.

The active matrix substrate 700 includes a substrate 711, a base film 712 that is formed on a surface of the substrate 711, the first thin film transistor 710A that is formed on the base film 712, and the second thin film transistor 710B that is formed on the base film 712. The first thin film transistor 710A is a crystalline silicon TFT that has an active region which primarily contains crystalline silicon. The second thin film transistor 710B is an oxide semiconductor TFT that has an active region which primarily contains an oxide semiconductor. The first thin film transistor 710A and the second thin film transistor 710B are integrally built on the substrate 711. The “active region” here is assumed to refer to an area in which a channel is formed, of the semiconductor layer that is the active layer of the TFT.

The first thin film transistor 710A has a crystalline silicon semiconductor layer (for example, a low-temperature polysilicon layer) 713 that is formed on the base film 712, a first insulating layer 714 that covers the crystalline silicon semiconductor layer 713, and a gate electrode 715A that is provided on the first insulating layer. A portion that is positioned between the crystalline silicon semiconductor layer 713 and the gate electrode 715A, of the first insulating layer 714 functions as a gate insulating film of the first thin film transistor 710A. The crystalline silicon semiconductor layer 713 has a region (an active region) 713c on which a channel is formed, and has a source region 713s and a drain region 713d that are positioned to both the sides, respectively, of the active region. In this example, a portion that overlaps the gate electrode 715A with the first insulating layer 714 in between, of the crystalline silicon semiconductor layer 713 is the active region 713c. The first thin film transistor 710A further has a source electrode 718sA and a drain electrode 718dA that are connected to the source region 713s and the drain region 713d, respectively. The source and drain electrodes 718sA and 718dA may be provided on an inter-layer insulating film (here, a second insulating layer 716) that covers the gate electrode 715A and the crystalline silicon semiconductor layer 713, and may be connected to the crystalline silicon semiconductor layer 713 within a contact hole that is formed in the inter-layer insulating film.

The second thin film transistor 710B has a gate electrode 715B that is provided on the base film 712, the second insulating layer 716 that covers the gate electrode 715B, and the oxide semiconductor layer 717 that is positioned on the second insulating layer 716. As illustrated, the first insulating layer 714 that is the gate insulating film of the first thin film transistor 710A may extend up to an area in which the second thin film transistor 710B is set to be formed. In this case, the oxide semiconductor layer 717 may be formed on the first insulating layer 714. A portion that is positioned between the gate electrode 715B and the oxide semiconductor layer 717, of the second insulating layer 716 functions as a gate insulating film of the second thin film transistor 710B. The oxide semiconductor layer 717 has a region (active region) 717c in which a channel is formed, and a source contact area 717s and a drain contact area 717d that are positioned to both the sides, respectively, of the active region. In this example, a portion that overlaps the gate electrode 715B with the second insulating layer 716 in between, of the oxide semiconductor layer 717 is the active region 717c. Furthermore, the second thin film transistor 710B further has a source electrode 718sB and a drain electrode 718dB that are connected to the source contact area 717s and the drain contact area 717d, respectively. Moreover, it is also possible that the base film 712 is not provided on the substrate 711.

The thin film transistors 710A and 710B are covered with a passivation film 719 and a flattening film 720. In the same manner as in the embodiment described above, as the passivation film 719, a multi-layered film of which a lower layer is a silicon oxide layer and of which an upper layer is a silicon nitride layer. In the second thin film transistor 710B that functions as the pixel TFT, the gate electrode 715B is connected to the gate bus line (not illustrated), the source electrode 718sB to the source bus line (not illustrated), and the drain electrode 718dB to the pixel electrode 723. A video signal is supplied to the source electrode 718sB through the source bus line, and necessary electric potential is written to a pixel electrode 723 based on a gate signal from the gate bus line.

A transparent conductive layer 721 is formed as a common electrode on the flattening film 720, and a third insulating layer 722 is formed between a transparent conductive layer (a common electrode) 721 and the pixel electrode 723. In this case, an opening in the shape of a slit may be provided in the pixel electrode 723.

In this example, the drain electrode 718dB is connected to the corresponding pixel electrode 723 within an opening portion (a pixel contact hole) that is formed in the passivation film 719, the flattening film 720, and the third insulating layer 722. Although not illustrated, on the side wall of the pixel contact hole, the border 120 may be formed on a flank surface of the flattening film 720 (refer to FIG. 1(b)). Alternatively, at least a portion of a flank surface of the passivation film 719 may be covered with the flattening film 720 (refer to FIG. 5(b)).

The active matrix substrate 700, for example, can find application in display devices that operate in the Fringe Field Switching (FFS) mode. The FFS mode is a mode in compliance with the transverse electric field method in which a pair of electrodes is provided on one substrate and in which an electric field is applied to a liquid crystal molecule in a direction (the horizontal direction) parallel to a substrate surface. In this example, an electric field is generated that is expressed as a line of electric force which gets out of the pixel electrode 723, passes through a liquid crystal layer (not illustrated) and further through the opening in the shape of a slit in the pixel electrode 723, and gets to the common electrode 721. This electric field has a component in the horizontal direction with respect to the liquid crystal layer. As a result, the electric field in the horizontal direction can be applied to the liquid crystal layer. In a transverse electric field method, a liquid crystal molecule does not rise up from the substrate. Because of this, there is an advantage in that the transverse electric field method can realize a wider viewing angle than a longitudinal electric field method.

As the second thin film transistor 710B according to the present embodiment, the TFTs 101 and 201 according to the embodiment, which are described above, can be used that is described above with reference to FIGS. 1 and 5. In a case where the TFT 101 in FIG. 1 is used, the gate electrode 3, the gate insulating layer 5, the oxide semiconductor layer 7, the source electrode 8, and the drain electrode 9 in the TFT 101 may be caused to correspond to the gate electrode 715B, the second insulating layer (the gate insulating layer) 716, and the oxide semiconductor layer 717, and the source and drain electrodes 718sB and 718dB, respectively, which are illustrated in FIG. 8. Furthermore, the inorganic insulating layer 11, the organic insulating layer 12, the common electrode 15, the dielectric layer 17, and the pixel electrode 19, which are illustrated in FIG. 1, may be caused to correspond to the passivation film 719, the flattening film 720, the transparent conductive layer 721, the third insulating layer 722, and the pixel electrode 723, respectively.

Moreover, as a TFT (an inspection TFT) that constitutes the inspection circuit 770 that is illustrated in FIG. 7, the thin film transistor 710B that is an oxide semiconductor TFT may be used.

It is noted that, although not illustrated, the inspection TFT and the inspection circuit, for example, may be formed in an area in which the driver IC 750 that is illustrated in FIG. 7 is mounted. In this case, the inspection TFT is positioned between the driver IC 750 and the substrate 711.

In an example that is illustrated, the first thin film transistor 710A has the top gate structure in which the crystalline silicon semiconductor layer 713 is positioned between the gate electrode 715A and the substrate 711 (the base film 712). On the other hand, the second thin film transistor 710B has the bottom gate structure in which the gate electrode 715B is positioned between the oxide semiconductor layer 717 and the substrate 711 (the base film 712). By employing this structure, it is possible that the number of manufacturing processes or an increase in manufacturing cost is more effectively suppressed when two types of thin film transistors, thin film transistors 710A and 710B, are integrally formed on the same substrate 711.

TFT structures of the first thin film transistor 710A and the second thin film transistor 710B are not limited to those described above. For example, the thin film transistors 710A and 710B may have the same TFT structure. Alternatively, the first thin film transistor 710A may have the bottom gate structure, and the second thin film transistor 710B may have the top gate structure. Furthermore, in the case of the bottom gate structure, as in the thin film transistor 710B, a channel etch type may be available and an etch stop type may be available. Furthermore, a bottom contact type that the source electrode and the drain electrode are positioned under a semiconductor layer may be available.

The second insulating layer 716 that is the gate insulating film of the second thin film transistor 710B may extend up to an area in which the first thin film transistor 710A is formed, and may function as an inter-layer insulating film that covers the gate electrode 715A and the crystalline silicon semiconductor layer 713 of the first thin film transistor 710A. In a case where, in this manner, the inter-layer insulating film of the first thin film transistor 710A and the gate insulating film of the second thin film transistor 710B are formed within the same layer (the second insulating layer) 716, the second insulating layer 716 may have a multi-layered structure. For example, the second insulating layer 716 may have a multi-layered structure in which a layer (for example, a silicon nitride layer) with a hydrogen donation property of possibly supplying hydrogen and a layer (for example, a silicon oxide layer) with an oxygen donation property of possibly supplying oxygen, which is positioned on the layer with the hydrogen donation property of possibly supplying hydrogen, are included.

The gate electrode 715A of the first thin film transistor 710A and the gate electrode 715B of the second thin film transistor 710B may be formed within the same layer. Furthermore, the source and drain electrodes 718sA and 718dA of the first thin film transistor 710A, and the source and drain electrodes 718sB and 718dB of the second thin film transistor 710B may be formed within the same layer. The expression “electrodes are formed within the same layer” means that electrodes are formed using the same film (the conductive film). Accordingly, the increase in the number of manufacturing processes and in the manufacturing cost can be suppressed.

The first to third embodiments described above find application in active matrix substrates that use an oxide semiconductor TFT. The active matrix substrate can find application in various display devices, such as liquid crystal display devices, organic EL display devices, and inorganic EL display devices, and electronic devices that include the display device. The active matrix substrate is particularly used in a suitable manner for display devices that support a horizontal direction electric field drive method such as the FFS mode. It is noted that it is also possible that, for example, the active matrix substrate finds application in display devices that support a longitudinal electric field drive method such as a VA mode. In this case, the common electrode may be caused to function as an auxiliary capacity electrode and thus a transparent auxiliary capacitor may be formed from the common electrode, the pixel electrode, and the dielectric layer, within a pixel.

### INDUSTRIAL APPLICABILITY

The embodiments of the present invention can find wide application in various active matrix substrates that have an oxide semiconductor TFT. For example, the embodiments of the present invention can also find application in display devices, such as liquid crystal display devices, organic electroluminescence (EL) display devices, inorganic electroluminescence display devices, and MEMS display devices, imaging devices such as image sensor devices, and various electronic devices, such as image input devices, fingerprint reading devices, and semiconductor memories.

### REFERENCE SIGNS LIST

1 SUBSTRATE
3 GATE ELECTRODE
5 GATE INSULATING LAYER
7 OXIDE SEMICONDUCTOR LAYER
8 SOURCE ELECTRODE
8t SOURCE CONNECTION PORTION
9 DRAIN ELECTRODE
9a DRAIN ELECTRODE CONNECTION PORTION
11 INORGANIC INSULATING LAYER
11A SILICON OXIDE LAYER
11B SILICON NITRIDE LAYER
11p FIRST OPENING PORTION
11q FOURTH OPENING PORTION
12 ORGANIC INSULATING LAYER
12p SECOND OPENING PORTION
13 INTER-LAYER INSULATING LAYER
15 COMMON ELECTRODE
17 DIELECTRIC LAYER
17p THIRD OPENING PORTION
17q FIFTH OPENING PORTION
19 PIXEL ELECTRODE
19t UPPER CONNECTION PORTION
21 RESIST MASK
28 NOTCHED PORTION
100, 200, 700 ACTIVE MATRIX SUBSTRATE
101, 201 THIN FILM TRANSISTOR
102, 202, 703 PIXEL CONTACT PORTION
120 BORDER
121 FIRST PORTION
122 SECOND PORTION
CH1 PIXEL CONTACT HOLE
CH2 TERMINAL-PORTION CONTACT HOLE

1. An active matrix substrate that includes multiple pixel areas,
each comprising:
a substrate;
a thin film transistor that is supported on the substrate and has an oxide semiconductor layer as an active layer;
an inorganic insulating layer that is formed in such a manner as to cover the thin film transistor;
an organic insulating layer that is formed on the inorganic insulating layer;
a common electrode that is positioned on the organic insulating layer;
a pixel electrode that is positioned on the common electrode with a dielectric layer in between; and
a pixel contact portion that electrically connects the pixel electrode and a drain electrode of the thin film transistor,
wherein the inorganic insulating layer has a multi-layered structure that includes a silicon oxide layer which primarily contains silicon oxide, and a silicon nitride layer which is positioned on the silicon oxide layer and primarily contains silicon nitride,
wherein the dielectric layer primarily contains the silicon nitride,
wherein the pixel electrode is brought into contact with the drain electrode within a pixel contact hole that is provided in the inorganic insulating layer, the organic insulating layer, and the dielectric layer,
wherein the pixel contact hole is configured with a first opening portion, a second opening portion, and a third opening portion which are formed in the inorganic insulating layer, the organic insulating layer, and the dielectric layer, respectively,
wherein a flank surface of the first opening portion and a flank surface of the second opening portion are aligned, and
wherein the flank surface of the second opening portion includes
a first portion that is inclined at a first angle with respect to the substrate,
a second portion that is positioned above the first portion and is included at a second angle that is greater than the first angle, with respect to the substrate, and
a border that is positioned between the first portion and the second portion and of which an inclination angle with respect to the substrate discontinuously changes.

2. The active matrix substrate according to claim 1,
wherein the third opening portion is positioned within the first opening portion and the second opening portion, when viewed from a direction normal to the substrate 1.

3. The active matrix substrate according to claim 1,
wherein at the border, an angle that the first portion and the second portion make with respect to each other is equal to or greater than 120° and is equal to or smaller than 170°.

4. An active matrix substrate that includes multiple pixel areas, each comprising:
a substrate;
a thin film transistor that is supported on the substrate and has an oxide semiconductor layer as an active layer;
an inorganic insulating layer that is formed in such a manner as to cover the thin film transistor;
an organic insulating layer that is formed on the inorganic insulating layer;
a common electrode that is positioned on the organic insulating layer;
a pixel electrode that is positioned on the common electrode with a dielectric layer in between; and
a pixel contact portion that electrically connects the pixel electrode and a drain electrode of the thin film transistor,
wherein the inorganic insulating layer has a multi-layered structure that includes a silicon oxide layer which primarily contains silicon oxide, and a silicon nitride layer which is positioned on the silicon oxide layer and primarily contains silicon nitride,
wherein the dielectric layer primarily contains the silicon nitride,
wherein the pixel electrode is brought into contact with the drain electrode within a pixel contact hole that is provided in the inorganic insulating layer, the organic insulating layer, and the dielectric layer,
wherein the pixel contact hole is configured with a first opening portion, a second opening portion, and a third opening portion which are formed in the inorganic insulating layer, the organic insulating layer, and the dielectric layer, respectively,
wherein at least a portion of the flank surface of the first opening portion is covered with the organic insulating layer, and
wherein the third opening portion is positioned within the first opening portion and the second opening portion, when viewed from the direction normal to the substrate.

5. The active matrix substrate according to claim 4,
wherein the second opening portion is positioned within the first opening portion, when viewed from the direction normal to the substrate.

6. The active matrix substrate according to claim 4,
wherein only a part of the second opening portion is positioned within the first opening portion, when viewed from the direction normal to the substrate.

7. The active matrix substrate according to claim 1, the pixel area further comprising:
a terminal portion,
wherein the terminal portion includes
a source connection portion that is positioned on the gate insulating layer,
the inorganic insulating layer that extends on the source connection portion,
the dielectric layer that extends on the inorganic insulating layer and is brought into contact with an upper surface of the inorganic insulating layer, and
an upper connection portion that is positioned on the dielectric layer,
wherein the upper connection portion is brought into contact with the source connection portion within a terminal-portion contact hole that is formed in the inorganic insulating layer and the dielectric layer,
wherein the terminal-portion contact hole is configured with a fourth opening portion and a fifth opening portion that are formed in the inorganic insulating layer and the dielectric layer, respectively, and
wherein, when viewed from the direction normal to the substrate 1, the fifth opening portion is positioned within the fourth opening portion, and a flank surface of the fourth opening portion is covered with the dielectric layer.

8. The active matrix substrate according to claim 1,
wherein the thin film transistor has a channel etch structure.

9. The active matrix substrate according to claim 1,
wherein the oxide semiconductor layer of the thin film transistor contains an In—Ga—Zn—O-based semiconductor.

10. The active matrix substrate according to claim 9,
wherein the oxide semiconductor layer contains a crystalline portion.

11. The active matrix substrate according to claim 1,
wherein the oxide semiconductor layer has a multi-layered structure.

12. A method of manufacturing an active matrix substrate, the method comprising:
(a) a process of forming a thin film transistor of which an active layer is an oxide semiconductor layer, on a substrate;
(b) a process of forming an inorganic insulating layer in such a manner as to cover the thin film transistor, the process in which the inorganic insulating layer has a multi-layered structure that includes a silicon oxide layer which primarily contains silicon oxide, and a silicon nitride layer which is positioned on the silicon oxide layer and primarily contains silicon nitride;
(c) a process of forming on the inorganic insulating layer an organic insulating layer that has a second opening portion through which a portion of the inorganic insulating layer is exposed;
(d) a process of forming a resist mask on an upper surface of the organic insulating layer and a portion of a flank surface of the second opening portion, the process in which an end portion of the resist mask is positioned on the flank surface of the second opening portion and in which a portion of the organic insulating layer is exposed through the resist mask;
(e) a process of performing patterning of the inorganic insulating layer using the resist mask, the process in which, by performing the patterning, not only is formed a first opening portion through which a portion of the drain electrode is exposed, in the inorganic insulating layer, but a surface layer of a portion that is exposed through the resist mask, of the organic insulating layer is also etched;
(f) a process of forming a common electrode on the organic insulating layer;
(g) a process of forming on the organic insulating layer a dielectric layer that is positioned within the second opening portion and first opening portion and has a third opening portion through which a portion of the drain electrode is exposed, the process in which the dielectric layer primarily contains silicon nitride; and
(h) a process of forming a pixel electrode that is brought into contact with the drain electrode within the pixel contact hole, on the dielectric layer and within the pixel contact hole.

13. A method of manufacturing the active matrix substrate according to claim 4, the method comprising:
(a) a process of forming a thin film transistor of which an active layer is an oxide semiconductor layer, on a substrate;
(b) a process of forming an inorganic insulating layer in such a manner as to cover the thin film transistor, the process in which the inorganic insulating layer has a multi-layered structure that includes a silicon oxide layer which primarily contains silicon oxide, and a silicon nitride layer which is positioned on the silicon oxide layer and primarily contains silicon nitride;
(c) a process of forming a first opening portion through which a portion of a drain electrode of the thin film transistor is exposed, in the inorganic insulating layer;
(d) a process of forming on the inorganic insulating layer and within the first opening portion an organic insulating layer that is positioned in such a manner as to cover at least a portion of a flank surface of the first opening portion and has a second opening portion through which a portion of the drain electrode is exposed;
(e) a process of forming a common electrode on the organic insulating layer;
(f) a process of forming on the organic insulating layer a dielectric layer that has an third opening portion that is positioned within the second opening portion and the first opening portion and through which a portion of the drain electrode is exposed, the process in which the dielectric layer primarily contains silicon nitride and in which, when viewed from a direction normal to the substrate, the third opening portion is positioned within the first opening portion and the second opening portion; and
(g) a process of forming a pixel electrode that is brought into contact with the drain electrode within a pixel contact hole, on the dielectric layer and within the pixel contact hole that is configured with the first opening portion, the second opening portion, and the third opening portion.
